(19) United States
(12) Patent Application Publication
(10) Pub. No.: US 2025/0324576 A1
(43) Pub. Date: Oct. 16, 2025

(54) FORMING AIR GAPS BETWEEN BIT LINES IN SEMICONDUCTOR DEVICES

(71) Applicant: Yangtze Memory Technologies Co., Ltd., Wuhan (CN)

(72) Inventors: Xiaoping HE, Wuhan (CN); Hsing-An LO, Wuhan (CN)

(21) Appl. No.: 18/770,648

(22) Filed: Jul. 11, 2024

(30) Foreign Application Priority Data
Apr. 16, 2024 (CN) 202410458291.2

(51) Int. Cl. H10B 12/00

(52) U.S. Cl. CPC H10B 12/485; H10B 12/0335; H10B 12/05; H10B 12/315; H10B 12/482

(57) ABSTRACT

Systems, devices, and methods for forming air gaps between bit lines in a semiconductor device are provided. In one aspect, the semiconductor device includes a memory array of memory cells and bit lines coupled to the memory array. Adjacent bit lines of the bit lines are separated by an isolating region along a first direction. The isolating region extends along a second direction perpendicular to the first direction. The isolating region includes an air gap. Along the second direction, an end of the air gap is above an adjacent end of a bit line of the adjacent bit lines.

### CROSS-REFERENCE TO RELATED APPLICATIONS

This application claims priority to Chinese Patent Application No. 202410458291.2, filed on Apr. 16, 2024, which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory DRAMs. The semiconductor memory devices can have various structures to increase a density of memory cells and lines on a chip. A memory device normally includes a memory array of memory cells and control circuitries for facilitating operations of the memory array.

### SUMMARY

The present disclosure describes methods, devices, systems and techniques for forming air gaps between adjacent bit lines in semiconductor devices.

One aspect of the present disclosure features a semiconductor device, including a memory array of memory cells and bit lines coupled to the memory array. Adjacent bit lines of the bit lines are separated by an isolating region along a first direction. The isolating region extends along a second direction perpendicular to the first direction. The isolating region includes an air gap. Along the second direction, an end of the air gap is above an adjacent end of a bit line of the adjacent bit lines.

In some implementations, a memory cell of the memory cells includes a transistor and a capacitor. The transistor includes a transistor body extending along the second direction, a gate structure, and a first terminal and a second terminal on opposite ends of the transistor body. The first terminal of the transistor is coupled to the capacitor. The second terminal of the transistor is coupled to a corresponding bit line of the bit lines.

In some implementations, along the second direction, a distance between the end of the air gap and an end of the gate structure is greater than a distance between the adjacent end of the bit line and the end of the gate structure.

In some implementations, the air gap is surrounded by an isolating material.

In some implementations, the isolating material includes a low-k porous dielectric material.

In some implementations, the low-k porous dielectric material has a dielectric constant in a range from about 1.5 to about 3.5.

In some implementations, along the second direction, the end of the air gap is away the adjacent end of the bit line of the adjacent bit lines by a height. A ratio of the height to a width of the isolation region along the first direction is in a range from about 0 to about 0.8.

In some implementations, the height is in a range from about 3 nm to about 10 nm.

In some implementations, the air gap includes a first portion and a second portion that are arranged along the second direction. A width of the air gap along the first direction in the first portion is smaller than a width of the air gap along the first direction in the second portion.

In some implementations, the width of the air gap along the first direction gradually decreases towards the end of the air gap in the first portion of the air gap.

In some implementations, a ratio of a maximum width of the air gap along the first direction to a width of the isolation region along the first direction is greater than 0.6.

In some implementations, a ratio of a height of the air gap along the second direction to a width of the isolating region along the first direction is in a range from about 2 to about 5.

In some implementations, an aspect ratio of the air gap between a height of the air gap along the second direction and a width of the air gap is greater than or equal to 3.

Another aspect of the present disclosure features a method including: forming bit lines separated by a dielectric material. The dielectric material is etched between adjacent bit lines of the bit lines to form a trench between the adjacent bit lines along a first direction. An isolating region is formed in the trench between the adjacent bit lines. The isolating region extends along a second direction perpendicular to the first direction. The isolating region includes an air gap surrounded by an isolating material. Along the second direction, an end of the air gap is above an adjacent end of a bit line of the adjacent bit lines.

In some implementations, forming the isolating region in the trench between the adjacent bit lines includes introducing a gas mixture of a porous linkage material in vapor phase and oxygen gas into a reaction chamber.

In some implementations, the isolating region between the adjacent bit lines is formed using plasma enhanced chemical vapor deposition (PECVD).

In some implementations, forming the isolating region in the trench between the adjacent bit lines includes controlling a size of the air gap by adjusting a concentration of the porous linkage material.

In some implementations, the method also includes forming a capacitor and a transistor. The transistor includes a transistor body extending along the second direction, a gate structure, and a first terminal and a second terminal on opposite ends of the transistor body. The first terminal of the transistor is coupled to the capacitor. The second terminal of the transistor is coupled to a corresponding bit line of the bit lines.

In some implementations, along the second direction, a distance between the end of the air gap and an end of the gate structure is greater than a distance between the adjacent end of the bit line and the end of the gate structure.

Another aspect of the present disclosure features a system including a memory device configured to store data and a memory controller coupled to the memory device and configured to operate the memory device. The memory device includes a memory array of memory cells and bit lines coupled to the memory array. Adjacent bit lines of the bit lines are separated by an isolating region along a first direction. The isolating region extends along a second direction perpendicular to the first direction. The isolating region includes an air gap. Along the second direction, an end of the air gap is above an adjacent end of a bit line of the adjacent bit lines.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIG. 2 illustrates a cross-section view of example air gaps between bit lines.

FIGS. 3A-3B illustrate cross-section views of a part of the example semiconductor device during various stages of a fabrication process.

FIGS. 4A-4B illustrate cross-section views of example air gaps between bit lines.

FIG. 5 illustrates an example process to form the example semiconductor device or a part of the example semiconductor device.

FIG. 6 illustrates a block diagram of a system having one or more semiconductor devices.

It is to be understood that the various exemplary implementations shown in the figures are merely illustrative representations and are not necessarily drawn to scale.

### DETAILED DESCRIPTION

In memory arrays of a memory device, e.g., DRAM, multiple bit lines run parallel to each other. Due to close physical proximity of these bit lines, parasitic capacitance can develop. Parasitic capacitance can be influenced by insulating layers and/or other materials between adjacent bit lines. Parasitic capacitance can slow down read and write operations of memory cells. For example, during a read operation, a charge stored in the memory cell needs to be accurately sensed. The presence of parasitic capacitance can interfere with the sensing process, leading to errors or delays. Similarly, during a write operation, the bit lines need to be charged or discharged to write data into the memory cells. Parasitic capacitance can affect the speed and efficiency of the writing process.

Implementations of the present disclosure provide semiconductor devices and methods to form such semiconductor devices. In some implementations, a semiconductor device includes a memory array of memory cells and bit lines coupled to the memory array. Adjacent bit lines of the bit lines are separated by an isolating region along a first direction. The isolating region extends along a second direction perpendicular to the first direction. The isolating region includes an air gap. Along the second direction, an end of the air gap is above an adjacent end of a bit line of the adjacent bit lines.

Implementations of the present disclosure can provide one or more of the following technical advantages and/or benefits. For example, air gaps can be utilized to separate adjacent bit lines. The relatively small dielectric constant of air in the air gaps (e.g., about 1) compared to silicon dioxide (e.g., about 3.9) can reduce capacitance between adjacent bit lines, thereby reducing crosstalk and improving an overall device performance. In addition, the techniques described in the present disclosure can form larger air gaps between adjacent bit lines, which leads to improved signal integrity and a lower susceptibility to noise. Moreover, the air gaps can extend beyond the ends of the adjacent bit lines in a direction away from the word lines or gate structures. This helps reduce fringing capacitance, which is the parasitic capacitance at the ends of two adjacent bit lines. Parasitic capacitance between two conductors can be more significant at the ends of adjacent bit lines compared to along their lengths, as the electric field lines tend to concentrate more at sharp points or ends of bit lines, leading to a higher capacitance. With the air gaps extending beyond the ends of the adjacent bit lines, the fringing capacitance at the ends of bit lines can also be reduced, thus further improving device performance. Further, the techniques described in the present disclosure can provide a porous low-k dielectric material surrounding the air gaps. The porous low-k dielectric material can also contribute to a reduction of the crosstalk between adjacent bit lines.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

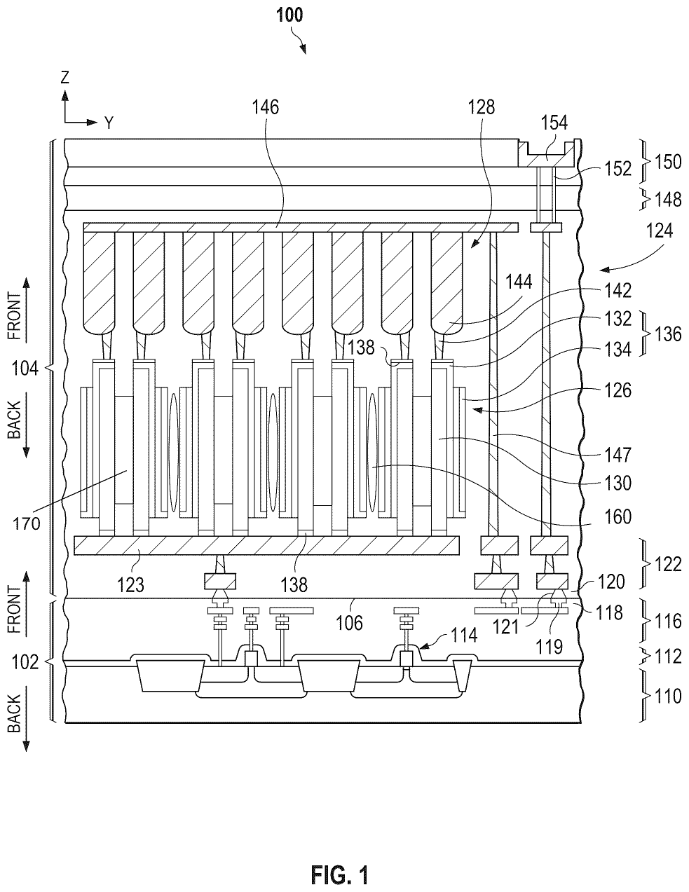

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

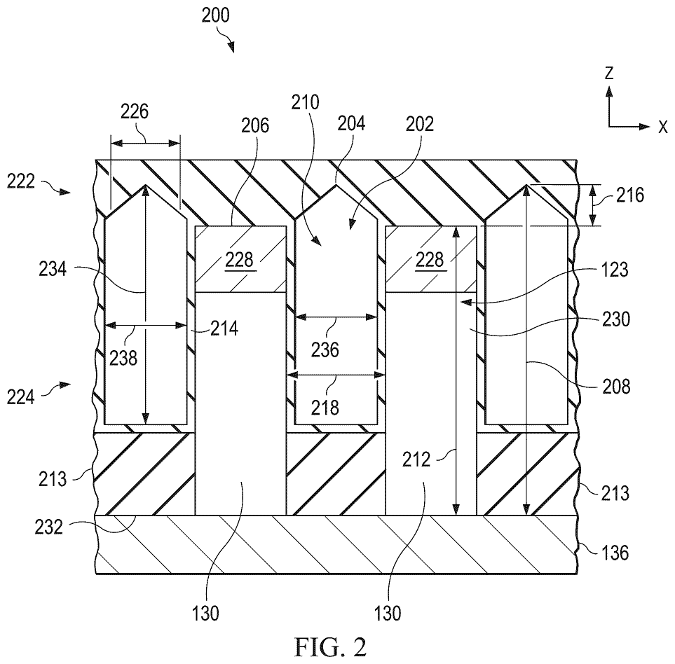

In some implementations, adjacent bit lines 123 are separated by an isolating region. The isolating region can include air gaps 210, e.g., as described with further details below in FIG. 2. The relatively small dielectric constant of air (e.g., about 1) in air gaps compared to silicon dioxide (e.g., about 3.9) can reduce a capacitance between adjacent bit lines, thereby reducing crosstalk and improving an overall device performance. Therefore, larger air gaps between bit lines 123 can be beneficial, which provides improved signal integrity and lower susceptibility to noise.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the Y direction). In some implementations, the gate dielectric 132 abuts one side of the semiconductor body 130, and the gate electrode 134 abuts the gate dielectric 132.

As shown in FIG. 1, in some implementations, the semiconductor body 130 has two ends (the upper end and lower end in FIG. 1) in the vertical direction (the z-direction), and at least one end (e.g., the lower end) extends beyond gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the semiconductor body 130, respectively, in the vertical direction (the z-direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively large dielectric constant of air in air gaps (e.g., about 4 times of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

In some implementations, instead of the trench isolation 160 having the air gap being disposed between adjacent vertical gates 134 of two adjacent rows of the vertical transistors 126, a shielding conductive structure 170 (e.g., including metal such as W) is disposed between adjacent semiconductor bodies 130 of two adjacent rows of vertical transistors 126. The shielding conductive structure 170 can be in contact with at least one of the adjacent semiconductor bodies 130 and can be coupled to a low voltage (e.g., a fixed negative voltage), which can reduce charge build-up in the memory cells 124, thereby mitigating the floating body effect in the memory cells 124. Moreover, by applying a fixed low voltage on the shielding conductive structure 170 between the memory cells 124, a threshold voltage of the memory cells 124 can be conveniently adjusted, which can reduce the overall manufacturing complexity and cost, and improve reliability of the memory cells 124. Further, the conductive structure 170 can be coupled out from a same side as word lines or a different side from the word lines. For example, the shielding conductive structure 170 can be coupled out from the back side of the second semiconductor structure 104. The shielding conductive structure 170 can be also referred as shielding conductive material.

As shown in FIG. 1, in some implementations, a capacitor 128 includes a first electrode 144 above and coupled to the source or drain 138 of vertical transistor 126, e.g., the upper end of the semiconductor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 1. In some implementations, the first end of the capacitor 128 is coupled to the first terminal of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron- or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminals 138 of the vertical transistors 126) through the substrate.

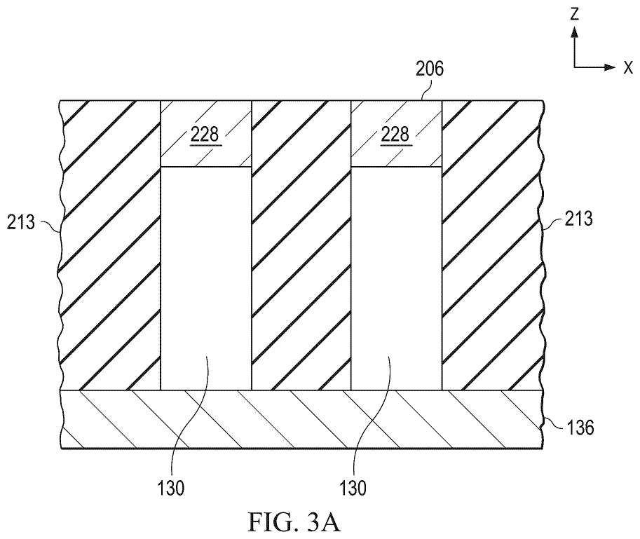

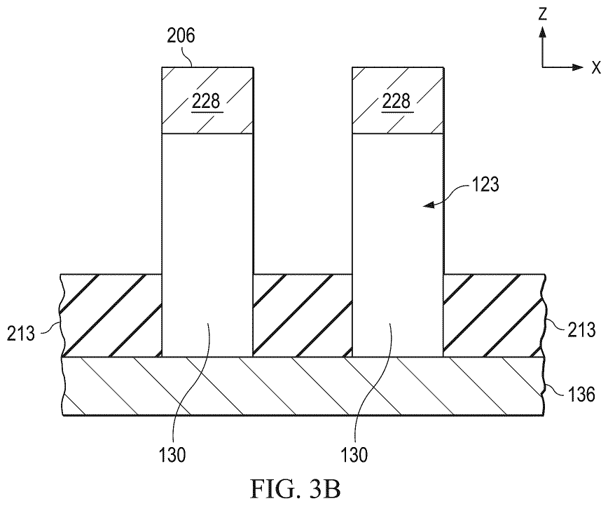

FIG. 2 illustrates a cross-section view of example air gaps between bit lines for a part of an example semiconductor device 200. The example semiconductor device 200 can be implemented as the semiconductor device 100 in FIG. 1. As shown in FIG. 1, the bit lines 123 can be coupled to the semiconductor bodies 130 of memory cells 124 of a memory array. Adjacent bit lines 123 can be separated by an isolating region 202 along a first direction, e.g., X direction or word line direction. The isolating region 202 can extend along a second direction perpendicular to the first direction. The second direction can be, e.g., the Z direction as shown in FIG. 2. The isolating region 202 can include an air gap 210. An end 204 of the air gap 210 is above an adjacent end 206 of a bit line 123 of the adjacent bit lines. In some implementations, a portion of the bit line 123 includes a metal material or a silicide material. As illustrated in FIG. 2, a top portion of the bit line, e.g., a portion farther away from the gate structure 136, includes a silicide material 228. In some implementations, the silicide material 228 includes without limitation to WSi, CoSi, CuSi, AlSi, or any other suitable metal silicides having higher conductivities than doped silicon. Another portion of the bit line 123 (e.g., a bottom portion 230) can be coupled to the semiconductor body 130. In some cases, the bottom portion 230 of the bit line 123 and the semiconductor body 130 can include a same semiconductor material such as silicon or polysilicon, e.g., as described with respect to FIG. 3B.

In some implementations, the air gap 210 is surrounded by an isolating material 214. In some implementations, the isolating material 214 includes a low-k (low dielectric constant) porous dielectric material. In some implementations, the porous dielectric material is created by introducing pores or voids into a material structure, which reduces its overall density. This can result in a lower dielectric constant k compared to silicon dioxide (SiO₂). In some implementations, the low-k porous dielectric material has a dielectric constant in a range (e.g., from about 1.5 to about 3.5). In some implementations, the low-k porous dielectric material includes, but without limitation to, silicon oxycarbide (SiOC), organosilicate glass (OSG), carbon-doped oxides (CDO), or black diamond (BD). In some implementations, the low-k porous dielectric material includes silicon oxide doped with carbon.

In some implementations, adjacent semiconductor bodies 130 are isolated by a dielectric material 213. The dielectric material 213 can be the same as or different from the isolating material 214. In some implementations, the dielectric material 213 includes silicon oxide.

In some implementations, along the second direction, e.g., the Z direction, a distance between the end 204 of the air gap 210 and an end 232 (e.g., a top surface) of the gate structure 136 is greater than a distance between the adjacent end 206 of the bit line 123 and the end 232 of the gate structure 136. As illustrated in FIG. 2, the distance between the end 204 of the air gap 210 and the end 232 of the gate structure 136 can be denoted as a first distance 208. The distance between the adjacent end 206 of the bit line 123 and the end 232 of the gate structure 136 can be denoted as a second distance 212. The first distance 208 can be greater than the second distance 212.

In some implementations, along the second direction, e.g., the Z direction, the end 204 of the air gap 210 is away from the adjacent end 206 of the bit line 123 of the adjacent bit lines by a height 216. A ratio of the height 216 to a width of the isolating region 202 along the first direction, e.g., the X direction, can be in a range, e.g., from about 0 to about 0.8. In some implementations, the height 216 is in a range, e.g., from about 3 nm to about 10 nm. A width 218 of the isolating region 202 can be a separation distance between two adjacent bit lines 123.

In some implementations, the air gap 210 includes a first portion 222 and a second portion 224 along the second direction, e.g., the Z direction. A width 226 of the air gap 210 along the first direction, e.g., the X direction or word line direction, in the first portion 222 is smaller than a width 238 of the air gap 210 in the second portion 224, as illustrated in FIG. 2. In some implementations, the width 226 of the air gap 210 in the first portion 222 refers to an average width of the air gap 210 in the first portion 222. Likewise, the width 238 of the air gap 210 in the second portion 224 refers to an average width of the air gap 210 in the second portion 224. In some implementations, the width 226 of the air gap 210 in the first portion 222 refers to any width of the air gap 210 in the first portion 222, except for the width at the interface of the first portion 222 and the second portion 224.

In some implementations, in the first portion 222, the width of the air gap 210 at a first location is smaller than the width of the air gap at a second location, where the first location is closer to the end 204 of the air gap 210 than the second location. In some implementations, as illustrated in FIG. 2, the width 226 of the air gap 210 gradually decreases towards the end 204 of the air gap 210 in the first portion 222 of the air gap 210. In some implementations, a cross section of the first portion 222 of the air gap 210 has a triangle shape or triangle-like shape and the end 204 of the air gap 210 can be a peak of the shape, as shown in FIG. 2. In some implementations, a cross section of the second portion 224 has a rectangular shape or rectangular-like shape, e.g., as shown in FIG. 2. The width 238 of the air gap 210 in the second portion 224 can be uniform in the second portion 224 along the second direction.

In some examples, a ratio of a maximum width of the air gap 210 along the first direction, e.g., the X direction or word line direction, to a width of the isolation region along the first direction is greater than 0.6, e.g., 0.7, 0.8, 0.9 or more. Thus, in the isolating region 202, the width of the air gap 210 can be greater than the combined width of the isolating material 214 along X direction, as shown in FIG. 2.

In some examples, a ratio of a height 234 of the air gap 210 along the second direction, e.g., the Z direction, to a width 218 of the isolating region 202 along the first direction, e.g., the X direction, is in a range, e.g., from about 2 to about 5.

In some implementations, an aspect ratio of the air gap 210 between a height 234 of the air gap 210 and a width 236 of the air gap 210 is greater than or equal to 3. For example, the height 234 of the air gap 210 can be 50 nm, while the width 236 of the air gap 210 can be 10 nm.

In some implementations, a spacer (not shown) is located between the bit lines 123 and the isolating materials 214. The spacer can include silicon nitride. The spacer can be utilized to protect the bit lines 123 from contamination during a manufacturing process.

FIGS. 3A-3B illustrate cross-section views of a part of an example semiconductor device during various stages of a fabrication process. As shown in FIG. 3A, multiple semiconductor bodies 130 can be formed. Each semiconductor body 130 can extend along Z direction. Adjacent semiconductor bodies 130 can be arranged along X direction (e.g., word line direction, as shown in FIG. 3A) and/or Y direction (e.g., bit line direction, as shown in FIG. 1). Adjacent semiconductor bodies 130 can be separated by the dielectric material 213. In some implementations, the dielectric material 213 includes, but not limited to, silicon oxide, silicon nitride, silicon oxynitride, or any combination thereof.

The gate structure 136 can be deposited adjacent to the semiconductor bodies 130 to form gate oxide. The gate structure 136 can extend along the word line direction, e.g., X direction. The gate structure 136 can include a gate dielectric 132 and a gate electrode 134 (e.g., as illustrated in FIG. 1). The gate dielectric 132 can include a dielectric material in contact with the semiconductor bodies 130. The dielectric material can include silicon oxide, silicon nitride, or high-K dielectric material including, but not limited to, Al₂O₃, HfO₂, Ta₂O₅, ZrO₂, TiO₂, any material with a dielectric constant higher than or equal to 3.9, or any combination thereof. The gate electrode 134 can abut the gate dielectric 132. In some implementations, the gate electrode 134 includes a conductive material including, but not limited to, W, Co, Cu, Al, TiN, TaN, polysilicon, silicide, or any combination thereof. In some implementations, the gate electrode 134 includes multiple conductive layers, such as a W layer over a TiN layer.

A silicide material 228 can be formed by performing a silicidation process at exposed upper ends of semiconductor bodies 130. The silicidation process can involve depositing a metal at the exposed upper ends of semiconductor bodies 130, followed by an annealing process. During annealing, the deposited metal can react with silicon on the semiconductor bodies 130 to form a layer of silicide at the metal-silicon interface. In some implementations, the silicide material 228 includes, but without limitation to, WSi, CoSi, CuSi, AlSi, or any other suitable metal silicides.

As illustrated in FIG. 3B, the dielectric material 213 can be partially etched or removed to expose sidewalls of upper portions of the semiconductor bodies 130. Accordingly, trenches can be formed between adjacent upper portions of the semiconductor bodies 130. This exposed upper portion of the semiconductor bodies 130 can be employed as the bit lines 123. The etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

In some implementations, the exposed upper portion of the semiconductor bodies 130, e.g., bit lines 123, are doped such that the dopants or dopant levels of the bit lines 123 are different from that of the remaining portion of the semiconductor bodies 130. The remaining portion of the semiconductor bodies 130 can be the segment of the semiconductor bodies 130 not utilized as the bit lines 123. In some implementations, the bit lines 123 are doped with N+ type dopants (e.g., Phosphorus (P) or Arsenic (As)) or P-type dopants (e.g., Boron (B) or Gallium (Ga)) at a desired doping level.

In some implementations, the semiconductor bodies 130 and the gate structure 136 are formed from the front side of a substrate (not shown), while the silicide materials 228 and air gaps 210 are formed from the back side of the substate. This process can involve flipping the substrate and thinning or polishing the back side of the substrate before forming silicide materials 228 and air gaps 210. A carrier wafer can be utilized which is bonded with the front side of the substrate during this process. The carrier wafer can provide mechanical support during subsequent processing steps, e.g., polishing the backside of the substrate, forming silicide materials 228 and air gaps 210.

Although not shown, it is understood that semiconductor bodies 130 can extend further along the negative Z direction beyond the gate structure 136. The lower end of the semiconductor bodies 130, e.g., the end in the negative Z direction, can be coupled to the capacitors 128, as illustrated FIG. 1. It is further understood the positive Z direction in FIGS. 2-4B can be opposite to the positive Z direction in FIG. 1.

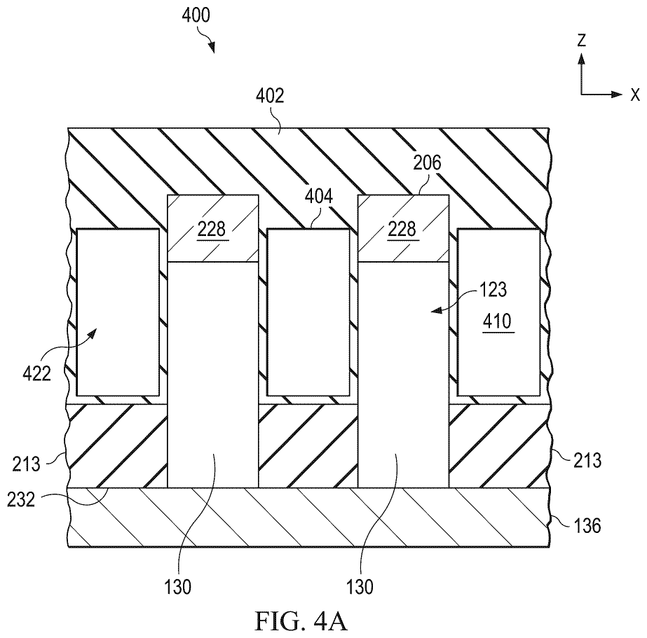

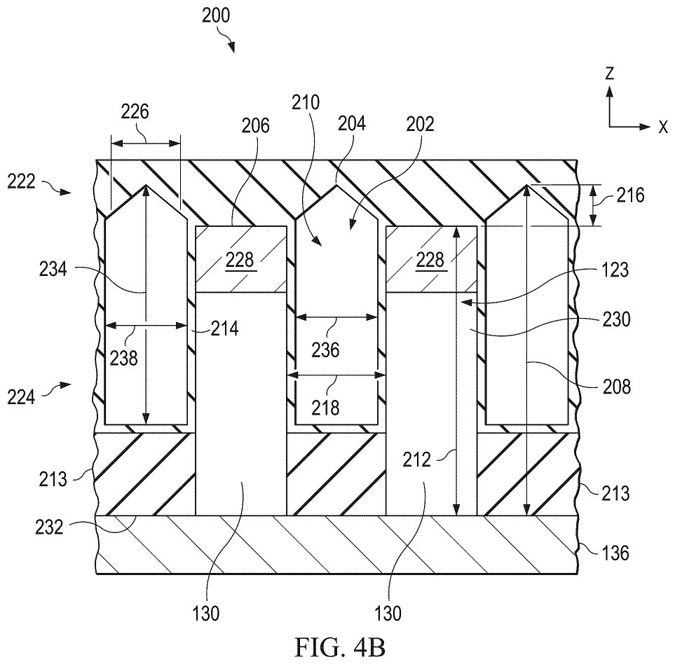

FIGS. 4A-4B illustrate cross-section views of example air gaps between bit lines 123. As illustrated in FIG. 4A, to form an isolating region 422 in a part of a semiconductor device 400, a separation material 402 can be deposited into the trenches between the bit lines 123. In some implementations, the separation material 402 is a dielectric material including, but not limited to, silicon oxide, silicon nitride, silicon oxynitride, or any combination thereof. In some implementations, the separation material 402 is deposited using Plasma-Enhanced Chemical Vapor Deposition (PECVD). In some implementations, the PECVD deposition process utilizes a precursor gas silane (SiH₄) as one of the primary reactants for film deposition. Silane can be used to deposit silicon-containing thin films, such as silicon dioxide (SiO₂) or silicon nitride (Si₃N₄). In some implementations, due to high aspect ratio of trenches between adjacent bit lines 123, air gaps 410 are formed between adjacent bit lines 123, which is surrounded by the separation material 402 as illustrated in FIG. 4A. In some implementations, the air gap 410 is narrow such that a width of the air gap 410 along X direction (e.g., the word line direction) is smaller than the combined width of the separation material 402 along the same direction. In some implementations, the air gap 410 doesn't extend beyond the isolating region 422 between adjacent bit lines 123 along the positive z direction. In other words, a distance between the end 404 of the air gap 410 and the end 232 of the gate structure 136 is smaller than a distance between the adjacent end 206 of the bit line 123 and the end 232 of the gate structure 136.

As illustrated in FIG. 4B, which is same as or substantially similar to FIG. 2, the isolating material 214 can be deposited into the trenches between the bit lines 123. In some implementations, the isolating material 214 includes, but not limited to, silicon oxide, silicon nitride, silicon oxynitride, or any combination thereof. In some implementations, the deposition of the isolating material 214 utilizes a chain-type precursor with a porous linkage material. The porous linkage material can include a CH₃ groups (methyl groups). The chain-type precursor can be utilized to grow a low-K dielectric material. The molecular units in the chain-type precursor can be arranged in a linear fashion, resembling one or more chains. The linear nature of the chain can facilitate controlled growth during deposition processes. In addition, the CH₃ groups can be susceptible for breaking during deposition process. When a CH₃ group breaks, it can promote growth along a specific direction, e.g., the Y-axis in FIG. 4B. Controlled breaking and growth along the Y-axis can contribute to improved film uniformity. During growth, voids or empty spaces can form within the isolating material 214. These voids can arise due to various factors, e.g., breakage of CH₃ groups, incomplete filling of the trenches, inadequate bonding between the precursor molecules, or the release of gases or solvents during the deposition process. Voids can lead to the formation of a porous material, e.g., the isolating materials 214. The presence of these voids can reduce the overall density of the isolating materials 214, thereby lowering its dielectric constant k. This reduction in dielectric constant can be beneficial in semiconductor manufacturing because it can help to decrease parasitic capacitance between adjacent bit lines 123.

In some implementations, the isolating region 202 between the adjacent bit lines 123 is formed using plasma enhanced chemical vapor deposition (PECVD). In some implementations, the deposition process involves introducing a gas mixture of a porous linkage material of the chain-type precursor in vapor phase and oxygen gas into a reaction chamber. In some implementations, the porous linkage material has one or more chemical elements including silicon (Si), carbon (C), Oxygen (O), and Hydrogen (H). In some implementations, a chemical link between two or more chemical elements or chemical compounds in the porous linkage material is breakable during forming the isolating region 202. For example, the porous linkage material can include a CH₃ group, and the CH₃ group can be breakable during deposition of the isolating material 214.

In some implementations, the air gaps 210 are formed in the isolating regions 202 by utilizing the porous linkage material as precursors. As described in FIG. 2, the air gaps 210 can extend beyond the adjacent bit lines 123 along positive z direction such that the distance between the end 204 of the air gap 210 and the end 232 of the gate structure 136 is greater than the distance between the adjacent end 206 of the bit line and the end 232 of the gate structure 136. The air gaps 210 can also have other characteristics or properties as described above in FIG. 2.

In some implementations, the air gaps 210 of the semiconductor device 200 is larger in dimensions, e.g., width, and/or height, than the air gap 410 of the semiconductor device 400. Larger air gaps 210 between bit lines 123 can decrease the parasitic capacitance between adjacent bit lines 123. Lower capacitance can reduce capacitive coupling, thus mitigating unwanted signal crosstalk and interference between neighboring bit lines 123. This can further lead to improved signal integrity and lower susceptibility to noise.

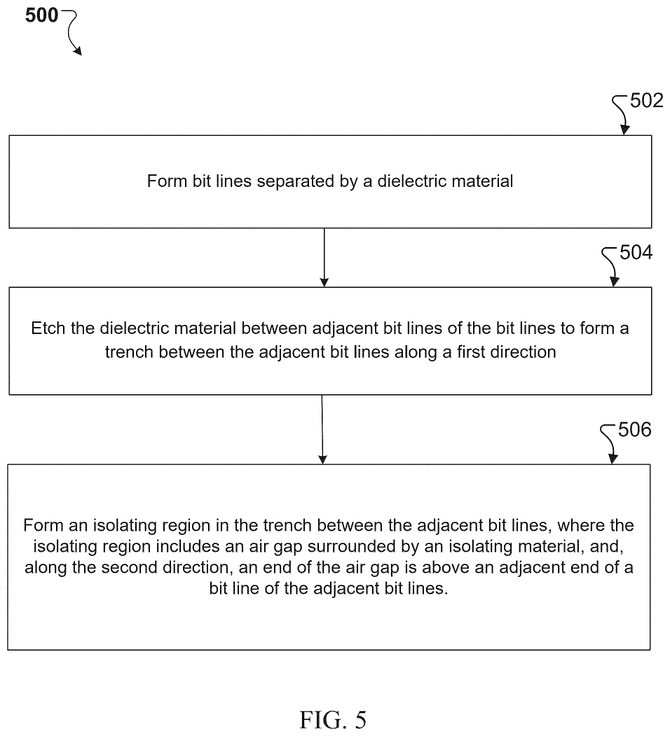

FIG. 5 illustrates an example process of forming an example of a semiconductor device or a part of the semiconductor device. The semiconductor device or the part of the semiconductor device can be, e.g., the semiconductor device 100 of FIG. 1, or the part of semiconductor device 200 of FIGS. 2-3B and 4B.

At step 502, the bit lines are formed and separated by a dielectric material. The bit lines can be, e.g., the bit lines 123 of FIGS. 1-4B. The dielectric material can be, e.g., the dielectric material 213 of FIGS. 2-4B.

At step 504, the dielectric material is at least partially etched between adjacent bit lines to form a trench between the adjacent bit lines along a first direction. The first direction can be, e.g., the X direction of FIGS. 2-4B.

At step 506, an isolating region in the trench is formed between the adjacent bit lines. The isolating region includes an air gap surrounded by an isolating material. Along the second direction, an end of the air gap is above an adjacent end of a bit line of the adjacent bit lines. The isolating region can be, e.g., the isolating region 202 of FIGS. 2 and 4B. The air gaps can be, e.g., the air gaps 210 of FIGS. 2 and 4B. The isolating material can be, e.g., the isolating material 214 of FIGS. 2 and 4B. The second direction can be, e.g., the Z direction of FIGS. 1-4B. The end of the air gap can be, e.g., the end 204 of the air gap 210 of FIGS. 2 and 4B. The adjacent end of a bit line can be, e.g., the adjacent end 206 of the bit line 123 of FIGS. 2-4B.

In some implementations, the isolating region between the adjacent bit lines is formed using plasma enhanced chemical vapor deposition (PECVD). In some implementations, forming the isolating region 202 in the trench between the adjacent bit lines 123 includes introducing a gas mixture of a porous linkage material in vapor phase and oxygen gas into a reaction chamber. In some implementations, a size of the air gap 210 is controlled by adjusting a concentration of the porous linkage material. In some implementations, a higher concentration of the porous linkage material leads to a higher deposition rate of the isolating material 214. In some cases, with a higher deposition rate, the isolating material 214 can build up near upper ends of the trenches more rapidly. Therefore, there can be less time for air to escape from the trench as it gets filled with the isolating material 214. This can lead to the formation of larger air gaps 210 within the trenches because the isolating material 214 may trap air as it fills the trenches.

In some implementations, the size of the air gap 210 is controlled by adjusting a radio-frequency (RF) power for the reaction chamber. In a PECVD process, RF power can be used to generate and control the plasma. The plasma can help to activate precursor gases, e.g., the porous linkage material, leading to chemical reactions and the deposition of the isolating material 214 onto a substrate. By adjusting the RF power, the density and energy of the plasma can be controlled, which in turn affects the deposition rate. Higher RF power can lead to increased deposition rates of the isolating material 214. As discussed above, higher deposition rates of the isolating material 214 can lead to formation of larger air gaps 210.

In some implementations, the porous linkage material has one or more chemical elements including silicon (Si), carbon (C), Oxygen (O), and Hydrogen (H).

In some implementations, a chemical link between two or more chemical elements or chemical compounds in the porous linkage material is breakable during forming the isolating region. For example, the porous linkage material can include a CH₃ group, and the CH₃ group can be breakable during deposition of the isolating material 214.

In some implementations, the method includes forming a capacitor and a transistor. The transistor includes a transistor body extending along the second direction, e.g., the Z direction, a gate structure, and a first terminal and a second terminal on opposite ends of the transistor body. The first terminal of the transistor is coupled to the capacitor. The second terminal of the transistor is coupled to a corresponding bit line of the bit lines. The capacitor can be, e.g., the capacitor 128 of FIG. 1. The transistor can be, e.g., the transistor 126 of FIG. 1. The transistor body can be, e.g., the semiconductor body 130 of FIGS. 1-4B. The gate structure can be, e.g., the gate structure 136 of FIGS. 1-4B. The first terminal and the second terminal can be, the source and drain 138 of FIG. 1.

In some implementations, along the second direction, a distance between the end of the air gap and an end of the gate structure is greater than a distance between the adjacent end of the bit line and the end of the gate structure. The end of the gate structure can be, e.g., the end 232 of the gate structure 136 of FIGS. 2-4B.

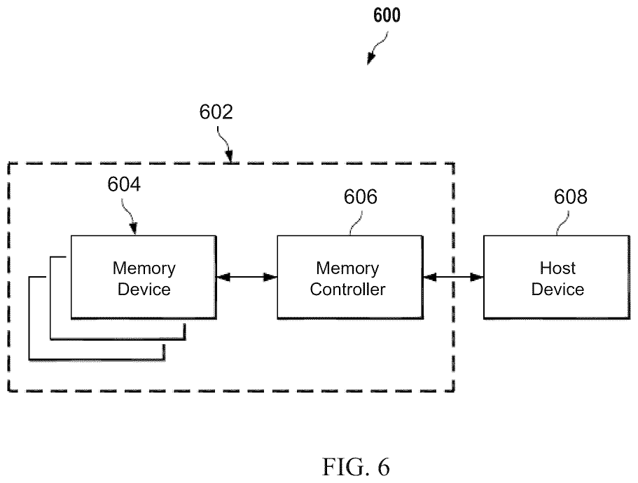

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIG. 1, or a part of the 3D semiconductor device 200 of FIGS. 2 and 4B, or a structure at an intermediate fabrication process of the 3D semiconductor device 200 of FIGS. 3A-3B.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a memory array of memory cells; and
bit lines coupled to the memory array, wherein adjacent bit lines of the bit lines are separated by an isolating region along a first direction, the isolating region extending along a second direction perpendicular to the first direction, the isolating region comprising an air gap,
wherein, along the second direction, an end of the air gap is above an adjacent end of a bit line of the adjacent bit lines.

2. The semiconductor device of claim 1, wherein a memory cell of the memory cells comprises a transistor and a capacitor, the transistor comprising a transistor body extending along the second direction, a gate structure, and a first terminal and a second terminal on opposite ends of the transistor body, and
wherein the first terminal of the transistor is coupled to the capacitor, and the second terminal of the transistor is coupled to a corresponding bit line of the bit lines.

3. The semiconductor device of claim 2, wherein, along the second direction, a distance between the end of the air gap and an end of the gate structure is greater than a distance between the adjacent end of the bit line and the end of the gate structure.

4. The semiconductor device of claim 1, wherein the air gap is surrounded by an isolating material.

5. The semiconductor device of claim 4, wherein the isolating material comprises a low-k porous dielectric material.

6. The semiconductor device of claim 5, wherein the low-k porous dielectric material has a dielectric constant in a range from about 1.5 to about 3.5.

7. The semiconductor device of claim 1, wherein, along the second direction, the end of the air gap is away the adjacent end of the bit line of the adjacent bit lines by a height, and
wherein a ratio of the height to a width of the isolation region along the first direction is in a range from about 0 to about 0.8.

8. The semiconductor device of claim 7, wherein the height is in a range from about 3 nm to about 10 nm.

9. The semiconductor device of claim 1, wherein the air gap comprises a first portion and a second portion that are arranged along the second direction, and wherein a width of the air gap along the first direction in the first portion is smaller than a width of the air gap along the first direction in the second portion.

10. The semiconductor device of claim 9, wherein the width of the air gap along the first direction gradually decreases towards the end of the air gap in the first portion of the air gap.

11. The semiconductor device of claim 1, wherein a ratio of a maximum width of the air gap along the first direction to a width of the isolation region along the first direction is greater than 0.6.

12. The semiconductor device of claim 1, wherein a ratio of a height of the air gap along the second direction to a width of the isolating region along the first direction is in a range from about 2 to about 5.

13. The semiconductor device of claim 1, wherein an aspect ratio of the air gap between a height of the air gap along the second direction and a width of the air gap is greater than or equal to 3.

14. A method, comprising:
forming bit lines separated by a dielectric material;
etching the dielectric material between adjacent bit lines of the bit lines to form a trench between the adjacent bit lines along a first direction; and
forming an isolating region in the trench between the adjacent bit lines, the isolating region extending along a second direction perpendicular to the first direction,
wherein the isolating region comprises an air gap surrounded by an isolating material, and, along the second direction, an end of the air gap is above an adjacent end of a bit line of the adjacent bit lines.

15. The method of claim 14, wherein forming the isolating region in the trench between the adjacent bit lines comprises: introducing a gas mixture of a porous linkage material in vapor phase and oxygen gas into a reaction chamber.

16. The method of claim 14, wherein the isolating region between the adjacent bit lines is formed using plasma enhanced chemical vapor deposition (PECVD).

17. The method of claim 15, wherein forming the isolating region in the trench between the adjacent bit lines comprises: controlling a size of the air gap by adjusting a concentration of the porous linkage material.

18. The method of claim 14, further comprising forming a capacitor and a transistor, the transistor comprising a transistor body extending along the second direction, a gate structure, and a first terminal and a second terminal on opposite ends of the transistor body, and
wherein the first terminal of the transistor is coupled to the capacitor, and the second terminal of the transistor is coupled to a corresponding bit line of the bit lines.

19. The method of claim 18, wherein, along the second direction, a distance between the end of the air gap and an end of the gate structure is greater than a distance between the adjacent end of the bit line and the end of the gate structure.

20. A system, comprising:
a memory device configured to store data, the memory device comprising:
a memory array of memory cells, and
bit lines coupled to the memory array, wherein adjacent bit lines of the bit lines are separated by an isolating region along a first direction, the isolating region extending along a second direction perpendicular to the first direction, the isolating region comprising an air gap, wherein, along the second direction, an end of the air gap is above an adjacent end of a bit line of the adjacent bit lines; and
a memory controller coupled to the memory device and configured to operate the memory device.
